(19) United States
(12) Patent Application Publication
(10) Pub. No.: US 2002/0137331 A1
(43) Pub. Date: Sep. 26, 2002

(54) Method of forming contact holes of reduced dimensions by using reverse-transcription process

(76) Inventor: Ching-Yu Chang, Yuan-Shan Hsiang (TW)

Correspondence Address: POWELL, GOLDSTEIN, FRAZER & MURPHY LLP, P.O. BOX 97223, WASHINGTON, DC, 20090-7223, US

(21) Appl. No.: 09/813,051

(22) Filed: Mar. 20, 2001

(51) Int. Cl. H01L 21/4763

(52) U.S. Cl. 438/637; 438/639

(57) ABSTRACT

First, a photoresist layer is formed on the substrate, wherein the photoresist layer has a plug-like structure. Then, an oxide layer is deposited on the plug-like structure. The oxide layer is etched to expose a portion of the plug-like structure. The plug-like structure is removed to formed a hole. Next, a conformal layer is deposited on the oxide layer and hole. Finally, the conformal oxide layer is etched, then the width of hole is smaller then original hole.

### BACKGROUND OF THE INVENTION

1. Field of the Invention

The present invention relates generally to a method for forming contact holes, and more particularly to a method of forming contact holes, line spacing or trenches of reduced dimension in an electronic structure by using reverse-transcription process.

2. Description of the Prior Art Contact windows (or holes) to a silicon or silicide layer are usually defined and etched in an insulating layer, i.e., a dielectric material layer, by using lithographic and dry etching techniques. A dry etching technique works anisotropicallly to enable the opening of contact holes that have high aspect ratios. Once formed, contact holes can be filled with a conducting material such as a metal to form vertical connections to a first level metal. Contact holes can also be made by a wet etch process. A wet etch process is carried out by immersing a wafer in an appropriate etchant solution or by spraying the wafer with a solution. When a wet etch process is used, the etching action is isotropic in nature such that the material is etched in both the lateral and the vertical directions. Lateral etching in a wet etch process produces undercutting under a mask which is undesirable in most fabrication processes. On the other hand, a dry etch process etches anisotropically and creates vertical sidewalls in a contact hole such that the top and the bottom of the hole have almost the same dimensions. The dry etch process is frequently used in modern sub-micron devices since it does not create undercutting problem and does not require or waste additional lateral area for a contact hole. The dry etching process further provides the benefits of reduced chemical hazard and waste treatment problems, easily achievable process automation and tool clustering. Two of the most widely used dry etching techniques are the plasma etching technique and the reactive ion etching technique.

Among the major lithographic techniques, optical, electron-beam, X-ray and ion-beam, optical lithographic technique using an ultraviolet (UV) light source has been the most important technology. The most commonly used ultraviolet light source for optical lithography are high-pressure arc lamps and laser sources. Major regions of the emitted light spectrum that are produced include the deep ultraviolet (DUV) region which is in the 100 to 300 μm range, the mid-UV region which is in the 300 to 360 μm range, and the near-UV region which is in the 360 to 450 μm range. For instance, when a mercury-xenon arc lamp is used, the dominant wavelengths produced are 254 μm (DUV), 365 μm (I-line), 405 μm (H-line) and 436 μm (G-line). Since most of the photoresist materials require a photo energy higher than 2.5 e^{V} for proper exposure, only wavelengths of 436 μm or shorter can be considered for lithography. When the minimal feature size desired is larger than about 2 μm, the full emitted spectrum of a mercury-xenon arc lamp can be used to expose the resist. For smaller feature sizes, the lens is corrected for one or two of the wavelengths and filters are used to remove the remainder of the spectrum. For instance, the I-line wavelength can be used for feature sizes about 0.4 μm. For even smaller feature sizes, i.e., below 0.4 μm, shorter wavelengths such as the DUV wavelength at 248 μm must be used with very sensitive DUV photoresist.

In modern VLSI manufacturing, state-of-the-art fabrication process for 16 Mbit or larger DRAMs is designed by the less than 0.4 μm process, i.e., a 0.25 μm process. The diameters of contact holes, for example, have to be less than 0.3 μm. Since the I-line capability is only 0.4 μm (with adequate process margin) for contacts, the shorter wavelength DUV technique and very sensitive DUV photoresist material must be used. The DUV technique and the DUV photoresist material are both high cost and therefore significantly increase the fabrication costs of the IC device.

FIGS. 1 and 2 illustrate a conventional process wherein a photolithographic method and a dry etching technique are used to form contact holes that have vertical sidewalls in a dielectric material layer. The figures illustrate the limitation on the minimum diameter of the contact holes that can be formed due to the resolution limit of the I-line wavelength. In FIG. 1, a dielectric layer 20 is deposited on top of the substrate 10. The substrate 10 can be a silicon layer and the dielectric film layer 20 can be a silicon oxide layer or a silicon nitride layer. On top of the dielectric film layer 20, a photoresist layer 30 is first deposited and then patterned to create openings 40. The photoresist layer 30 is patterned by an optical method using ultraviolet I-line wavelength and thus, the resolution is limited to 0.4 μm as shown by W1 in FIG. 1. After the photoresist layer 30 is exposed and developed, contact holes 50 having a diameter of W1 are dry etched in the dielectric film layer 20. Since a dry etching technique, i.e., a reactive ion etching technique, is capable of producing openings of vertical sidewalls, the contact holes 50 formed has substantially vertical sidewalls such that the top of the hole and the bottom of the hole have the same diameter of W1 (or 0.4 μm). When a contact hole smaller than 0.4 μm is desired, the more expensive and difficult photolithographic technique that utilizes deep UV wavelength and very sensitive photoresist material must be used.

### SUMMARY OF THE INVENTION

It is therefore an object of the present invention to provide a method for forming contact holes of reduced dimensions that is beyond the resolution limit of normal I-line photolithographic technique.

It is another object of the present invention to provide a method of forming cavities in an electronic device of reduced dimensions that does not require the use of expensive deep-UV photolithographic technique and deep-UV photoresist material.

It is another further object of the present invention to provide a method of forming cavities in a semiconductor device such as contact holes and line spacings of reduced dimensions by using reverse-transcription process.

It is yet another object of the present invention to provide a method of forming contact holes or line spacing of reduced dimensions by utilizing reverse-transcription process furthermore deposited a conformal layer.

It is still another object of the present invention to provide a method of forming contact holes of reduced dimensions by using dielectric sidewall spacers that are formed by depositing conformal layer and etched.

In order to be formed cavities in the dielectric layer such as contact holes, line spacings or trenches. First, a photoresist layer is formed on the substrate, wherein the photoresist layer has a plug-like structure. Then, an oxide layer is deposited on the plug-like structure. The oxide layer is etched to expose a portion of the plug-like structure. The plug-like structure is removed to formed a hole. Next, a conformal layer is deposited on the oxide layer and in the hole. Finally, the conformal oxide layer is etched, then the width of hole is smaller then plug-like formed a hole.

### BRIEF DESCRIPTION OF THE DRAWINGS

These and other objects, features and advantages of the present invention will become apparent from the following detailed description and the appended drawings in which:

FIG. 1 is an enlarged, cross-sectional view of a conventional semi-conducting substrate which has a dielectric layer and a patterned photoresist layer sequentially deposited and formed on top;

FIG. 2 is an enlarged, cross-sectional view of the conventional semiconductor device shown in FIG. 1 with contact holes of the same size as the contact openings formed in the dielectric material layer;

FIG. 3 is an enlarged, cross-sectional view of a invention semiconducting substrate which has a patterned photoresist layer sequentially deposited and formed on top;

FIG. 4 is an enlarged, cross-sectional view of the present invention semiconductor device shown in FIG. 3 after dielectric material layer deposited on top of a patterned photoresist layer;

FIG. 5 is an enlarged, cross-sectional view of the present invention semiconductor device shown in FIG. 4 after dielectric material layer etch back;

FIG. 6 is an enlarged, cross-sectional view of the present invention semiconductor device shown in FIG. 5 after photoresist layer removed;

FIG. 7 is an enlarged, cross-sectional view of the present invention semiconductor device shown in FIG. 6 after dielectric material layer is deposited over the remaining portions; and

FIG. 8 is an enlarged, cross-sectional view of the present invention semiconductor device shown in FIG. 7 after dielectric material layer is etched form sidewall spacer layers.

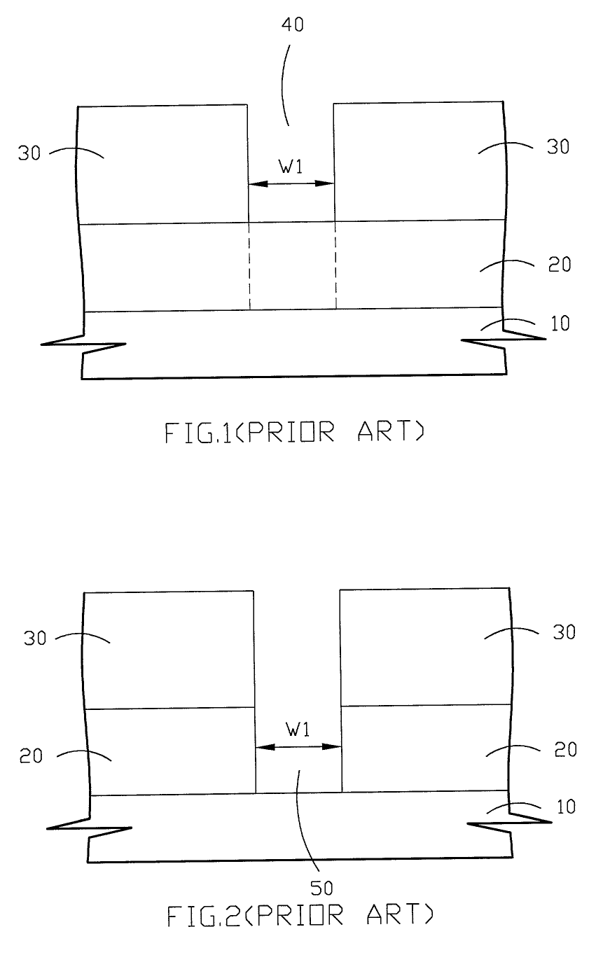

### DESCRIPTION OF THE PREFERRED EMBODIMENT

The present invention provides a method of forming cavities such as contact holes, line spacing or trenches of reduced dimensions in a semiconductor device by using reverse-transcription process.

In order to be formed cavities such as contact holes, line spacings or trenches in the dielectric layer. First, a photoresist layer must be deposited on the substrate. The photoresist layer can be of the type that is suitable for optical lithographic technique that utilizes I-line ultraviolet wavelength and that can be exposed and developed at relatively low cost.

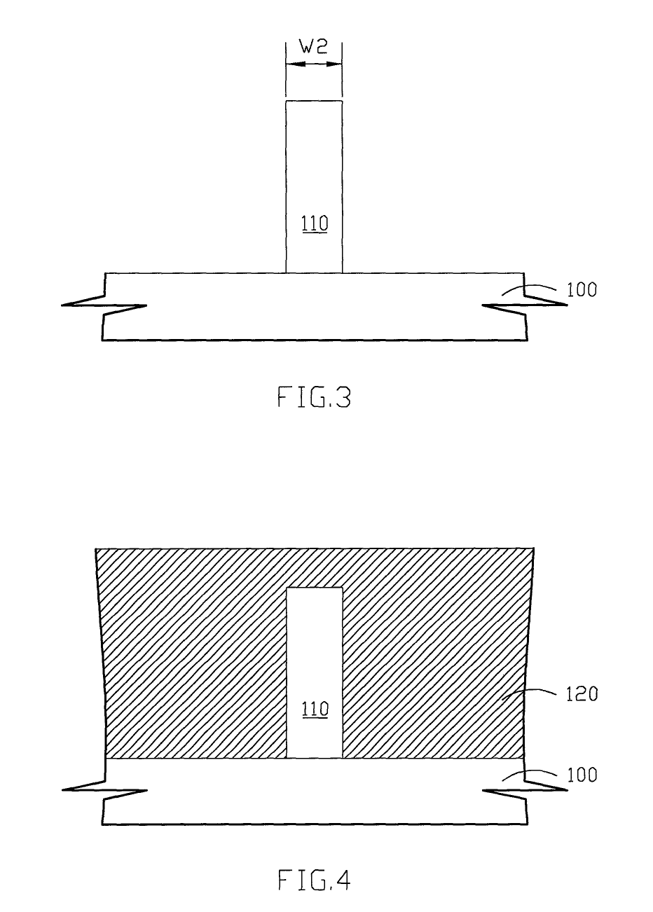

Referring initially to FIG. 3 where an enlarged, cross-sectional view is shown. First step, a photoresist layer 110 is deposited on substrate 100 wherein the photoresist layer 110 has a plug-like structure 100 act as island. Substrate 100 may be formed on a silicon layer or connections to a first level metal. The photoresist layer 110 region may as line.

Next, as Shown in FIG. 4, a first oxide layer 120 is formed as a dielectric material layer. The first oxide layer 120 can be formed by a thermal oxidation process or can be suitably deposited of any other dielectric material such as nitride or BPSG (boro-phosphor-silicate glass). Other suitable dielectric materials can also be deposited or spin on glass (SOG). And other method can used mixing of silane(SiH₄) and hydrodioxide (H₂O₂) solution deposited on the substrate 100 formed siliconoxide(SiO₂) layer. The operate temperature can controlled under room temperature, and backing temperature remained about 100° C. In this embodiment deposition of silane with hydrodioxide is preferred method.

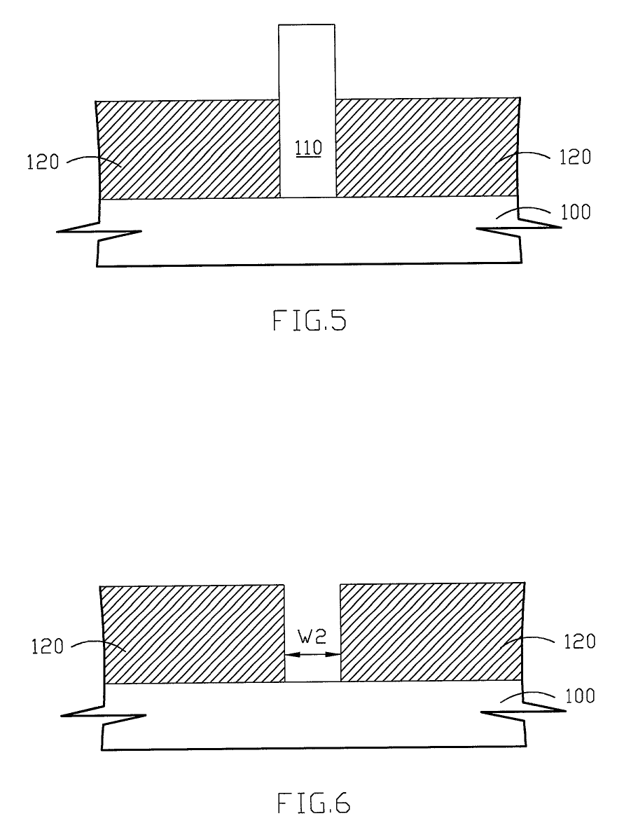

FIG. 5 shows a subsequent illustrative stage in this invention. The first oxide layer 120 is etched anisotropically or isotripically, using known methods, then exposing part of plug-like structure 110. Next, like as reverse-transcription, the plug-like structure 110 is then removed from first oxide layer 120 formed cavity (hole) 115. The width of cavity (hole) 115 is W2, referring to FIG. 6.

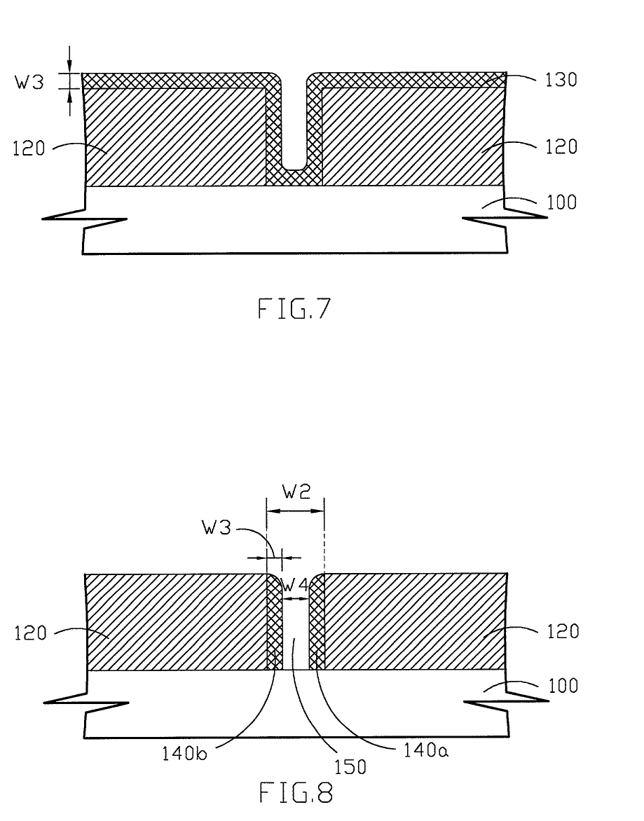

Next, shown in FIG. 7, a conformal second oxide layer 130 is deposited over the remaining portions of first oxide layer 120 and the cavity (hole) 115. The second oxide layer 130 is formed as a dielectric material layer. Dielectric material such as nitride or BPSG (boro-phosphor-silicate glass). Other suitable dielectric materials can also be deposited. Second oxide layer 130 has a thickness W3.

Shown in FIG. 8, next step, the second oxide layer 130 is etched anisotropically, using known methods, to form sidewall spacer 140a, 140b in the cavity (hole) 115. The width of each spacer 140a, 140b is W3. Thus, original cavity (hole) 115 width is W2, the width of two spacer of cavity inside is double W3. So, when width W2 of cavity (hole) 115 subtract width double W3 of spacer 140a and 140b, finally formed width W4 of cavity 150. The width W4 of cavity 150 is than original cavity (hole) 115 smaller.

Use this method, that can controlled thickness of deposited second oxide layer 130 obtained to expect the width of cavity 150. Therefor, the resolution of lithographic techniques are not limited. Apply to this invention make down size of a contact hole, the smallest line width or line-to-line separation.

While the present invention has been described in an illustrative manner, it should be understood that the terminology used is intended to be in a nature of words of description rather than of limitation.

Furthermore, while the present invention has been described in terms of a preferred embodiment, it is to be appreciated that those skilled in the art will readily apply these teachings to other possible variations of the inventions.

What is claimed is:

1. A method of forming cavities by using reverse-transcription process, said method comprising:
forming a photoresist layer on a substrate, wherein said photoresist layer has a plug-like structure;
depositing a first dielectric layer on said plug-like structure;
etching said first dielectric layer to expose a portion of said plug-like structure; and
removing said plug-like structure.

2. The method according to claim 1, wherein said formed cavities are selected from the group consisting of contact holes, line spacing and trenches.

3. The method according to claim 1, wherein materials of said first dielectric layer formed are selected from the group consisting of nitride, boro-phosphor-silicate glass (BPSG), spin on glass (SOG), silicon oxide and mixing of silane(SiH₄) and hydrodioxide (H₂O₂) solution.

4. The method according to claim 1, wherein said etching process are selected from wet and dry etch process.

5. A method of forming contact holes of reduced dimensions by using reverse-transcription process, said method comprising:
forming a photoresist layer on a substrate, wherein said photoresist layer has a plug-like structure;
depositing a first dielectric layer on said plug-like structure;
etching said first dielectric layer to expose a portion of said plug-like structure;
removing said plug-like structure to forming a hole;
depositing a conformal layer on said first dielectric layer and said hole; and
etching said conformal layer to form spacer in sidewall of said hole.

6. The method according to claim 5, wherein said formed contact holes are selected from the group consisting of line spacing and trenches.

7. The method according to claim 5, wherein materials of said first dielectric layer formed are selected from the group consisting of nitride, boro-phosphor-silicate glass (BPSG), spin on glass (SOG), silicon oxide and mixing of silane(SiH₄) and hydrodioxide (H₂O₂) solution.

8. The method according to claim 5, wherein said step of etching said first dielectric layer are selected from wet and dry etch process.

9. The method according to claim 5, wherein said conformal layer is dielectric material.

10. The method according to claim 9, wherein said dielectric material are selected from the group consisting of nitride and boro-phosphor-silicate glass (BPSG).

11. The method according to claim 5, wherein said step of etching said conformal layer is anisotropical.

12. A method of forming contact holes of reduced dimensions by using reverse-transcription process, said method comprising:
forming a photoresist layer on a substrate, wherein said photoresist layer has a plug-like structure;
depositing a first oxide layer on said plug-like structure;
etching said first oxide layer to expose a portion of said plug-like structure;
removing said plug-like structure to forming a hole;
depositing a conformal oxide layer on said first oxide layer and said hole; and
etching said conformal oxide layer to form spacer in sidewall of said hole.

13. The method according to claim 12, wherein said formed contact holes are selected from the group consisting of line spacing and trenches.

14. The method according to claim 12, wherein said materials of first oxide layer formed are selected from the group consisting of nitride, boro-phosphor-silicate glass (BPSG), spin on glass (SOG), silicon oxide and mixing of silane(SiH₄) and hydrodioxide (H₂O₂) solution.

15. The method according to claim 12, wherein said step of etching said first oxide layer are selected from wet and dry etch process.

16. The method according to claim 12, wherein said conformal oxide layer is dielectric material.

17. The method according to claim 16 wherein said dielectric material are selected from the group consisting of nitride and boro-phosphor-silicate glass (BPSG).

18. The method according to claim 12, wherein said step of etching said conformal oxide layer is anisotropical.
